(19) United States
(12) Patent Application Publication
(10) Pub. No.: US 2023/0307889 A1
(43) Pub. Date: Sep. 28, 2023

(54) VERTICAL CAVITY SURFACE-EMITTING LASER EPITAXIAL STRUCTURE HAVING A CURRENT SPREADING LAYER

(71) Applicant: VISUAL PHOTONICS EPITAXY CO., LTD., Taoyuan City (TW)

(72) Inventors: Van-Truong DAI, Taoyuan City (TW); Yu-Chung CHIN, Taoyuan City (TW); Chao-Hsing HUANG, Taoyuan City (TW); Jhao-Hang HE, Taoyuan City (TW)

(21) Appl. No.: 18/188,450

(22) Filed: Mar. 22, 2023

(30) Foreign Application Priority Data
Mar. 23, 2022 (TW) 111110938
Jun. 16, 2022 (TW) 111122449

(51) Int. Cl. H01S 5/183; H01S 5/02

(52) U.S. Cl. CPC H01S 5/18341; H01S 5/0208; H01S 5/18327

(57) ABSTRACT

A vertical cavity surface-emitting laser epitaxial structure having a current spreading layer is disclosed. The vertical cavity surface-emitting laser epitaxial structure includes a substrate, a first epitaxial region on the substrate, an active region on the first epitaxial region, and a current spreading layer disposed in the first epitaxial region. The current spreading layer includes an N-type dopant, and the N-type dopant is selected from a group consisting of Si, Se, and the combination thereof. The current spreading layer does not directly contact the active region.

### RELATED APPLICATIONS

This application claims priority to Taiwanese Application Serial Number 111110938, filed Mar. 23, 2022, and Taiwanese Application Serial Number 111122449, filed Jun. 16, 2022, all of which are herein incorporated by reference in their entireties.

### BACKGROUND

### Field of Invention

The present disclosure relates to a vertical cavity surface-emitting laser (VCSEL) epitaxial structure. More particularly, the present disclosure relates to a VCSEL epitaxial structure with a current spreading layer, that is suitable for fabrication high-density VCSEL array.

### Description of Related Art

A vertical cavity surface-emitting laser (VCSEL) epitaxial structure is used to manufacture VCSEL device, including VCSEL diode or a VCSEL array. The area of a bottom epitaxial region of the VCSEL array is multiple times to thousands of times larger than the area of the VCSEL die. If the current distribution area in the bottom epitaxial region of the VCSEL array is not enlarged accordingly, the resistance of the bottom epitaxial region would be huge, and the power conversion efficiency of the VCSEL array is poor.

US Patent publication No. 2018/0175587A1 discloses a VCSEL array. However, the current spreading layer 210 is disposed over the multiple quantum well layer 216, rather than below the multiple quantum well layer 216.

U.S. Pat. No. 6,549,556B1 discloses a current-spreading layer 116 below the active region 115. However, U.S. Pat. No. 6,549,556B1 is not related to a VCSEL array, the area of the bottom epitaxial region thereof is not too large for the current to spread evenly. U.S. Pat. No. 6,549,556B1 also fails to disclose that the current-spreading layer 116 is disposed in a bottom cavity. It must be noted, the bottom cavity of U.S. Pat. No. 6,549,556B1 is made of dielectric material, and no current would flow into the bottom cavity of U.S. Pat. No. 6,549,556B1.

### SUMMARY

According to some embodiments of the disclosure, a vertical cavity surface-emitting laser epitaxial structure having a current spreading layer is disclosed. The vertical cavity surface-emitting laser epitaxial structure includes a substrate, a first epitaxial region on the substrate, an active region on the first epitaxial region, and a current spreading layer disposed in the first epitaxial region. The current spreading layer includes an N-type dopant, and the N-type dopant is selected from a group consisting of Si, Se, and the combination thereof. The current spreading layer does not directly contact the active region.

According to some embodiments of the disclosure, a vertical cavity surface-emitting laser epitaxial structure having a current spreading layer is disclosed. The vertical cavity surface-emitting laser epitaxial structure includes a substrate, a first epitaxial region on the substrate, and a current spreading layer. The first epitaxial region includes a bottom distributed Bragg reflector (DBR) layer. The current spreading layer is disposed between the bottom DBR layer and the substrate. The current spreading layer includes an N-type dopant, and the N-type dopant is selected from a group consisting of Si, Se, and the combination thereof.

Compared to the VCSEL array without the current spreading layer disposed in the bottom epitaxial region, the current distribution area herein is larger. Therefore, the resistance of the bottom epitaxial region such as resistance of the bottom DBR layer can be reduced, and the power conversion efficiency of the VCSEL (array) is enhanced. Additionally, as the current spreading layer is spaced from the active region by a suitable distance, so the problem of the current spreading layer is absorbing the light emitted from the active region can be prevented, thereby keeping the light-emitting efficiency of the VCSEL array as bigger as VCSEL die.

The situation of the current spreading layer being spaced from the active region by a suitable distance includes disposing at least one semiconductor layer such as a spacer layer, a tunnel junction layer or other suitable semiconductor layer between the active region and the current spreading layer.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1a is a schematic view of a VCSEL epitaxial structure according to some embodiments of the disclosure, in which the current spreading layer is spaced from the active region by a suitable distance, and the ohmic contact layer is below the substrate;

FIG. 1b is a schematic view of a VCSEL epitaxial structure according to some embodiments of the disclosure, in which the current spreading layer is spaced from the active region by a suitable distance, and the ohmic contact layer is over the substrate;

FIG. 2 is a schematic view of a VCSEL epitaxial structure according to some embodiments of the disclosure, in which the current spreading layer and the tunnel junction layer are disposed in the bottom DBR layer;

FIG. 3 is a schematic view of a VCSEL epitaxial structure according to some embodiments of the disclosure, in which the tunnel junction layer is disposed on the bottom DBR layer;

FIG. 4 is a schematic view of a VCSEL epitaxial structure according to some embodiments of the disclosure, in which the current spreading layer is disposed on a conductive substrate;

FIG. 5 is a schematic view of a VCSEL epitaxial structure according to some embodiments of the disclosure, in which the current spreading layer is disposed in the ohmic contact layer and is located near the substrate;

FIG. 6 is a schematic view of a VCSEL epitaxial structure according to some embodiments of the disclosure, in which the first epitaxial region includes two current spreading layers; and

FIG. 7 shows the L-I-V curves for Embodiment 1 and the control group.

### DESCRIPTION OF THE EMBODIMENTS

The drawings illustrate embodiments of the disclosure and, together with the description, serve to explain the principles of the present disclosure. For better understanding the concept of the present disclosure, only parts of the structure of the laser diode is illustrated, and the laser diode is not limited to be consisted of the mentioned elements. The thickness ratios of the layers in the drawing are for example, the thicknesses of the layers can be adjusted according to real requirements.

Reference will now be made in detail to the present embodiments of the present disclosure, examples of which are illustrated in the accompanying drawings. Wherever possible, the same reference numbers are used in the drawings and the description to refer to the same or like parts.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items. Reference will now be made in detail to the present embodiments of the disclosure, examples of which are illustrated in the accompanying drawings. Wherever possible, the same reference numbers are used in the drawings and the description to refer to the same or like parts.

Furthermore, relative terms, such as “lower” or “bottom” and “upper” or “top”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper”, depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Various embodiments are provided in the present disclosure. The exemplary terms “in some embodiments” means that the mentioned particular features, structures, or limitations can be included in at least one of the embodiments of the present disclosure. The exemplary terms “in some embodiments” is not necessary be the same embodiment.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Additionally, the term “layer” can be a single layer or a multi-layer. A part of an epitaxial layer can be one layer or adjacent layers of the epitaxial layer.

The VCSEL (array) discussed in the present disclosure is a vertical resonant cavity surface-emitting laser (array), which can be a top-emitting type or bottom-emitting type vertical resonant cavity surface-emitting laser (array).

Generally, the laser diode can optionally include a buffer layer based on the real requirement. In some embodiments, the buffer layer can be made of the same material as that of the substrate. Disposing a buffer layer or not is not the point of the technical feature or the advantage described in the following embodiments. Although the exemplary embodiments described in the following description are related to the laser diode having the buffer layer, the concept of the following embodiments can be also applied to the laser diode without the buffer layer.

### Embodiments 1 and 2

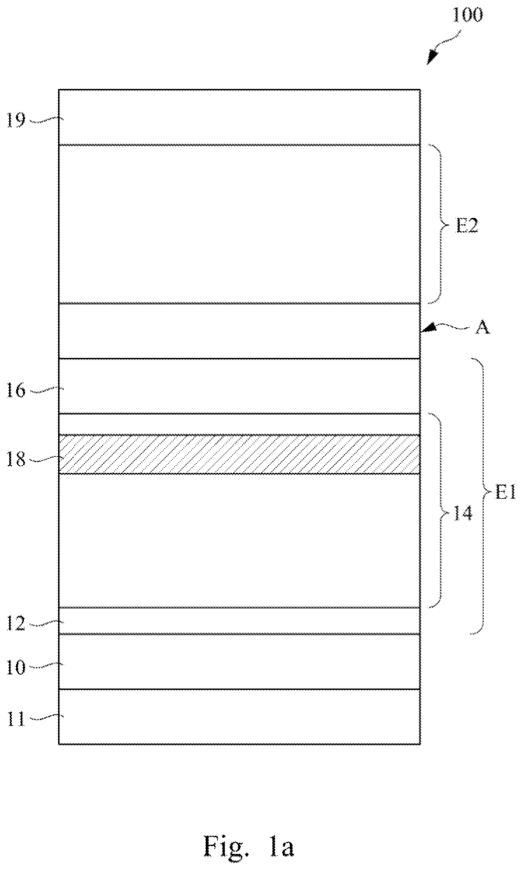

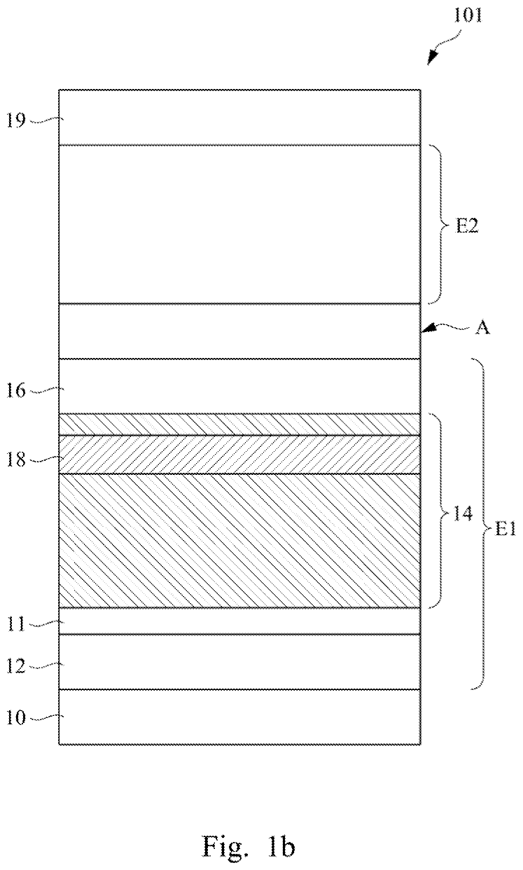

Reference is made to FIG. 1a, which is a schematic view of a VCSEL epitaxial structure according to some embodiments of the disclosure. The VCSEL epitaxial structure 100 includes a substrate 10, an ohmic contact layer 11, a first epitaxial region E1, an active region A, a second epitaxial region E2, a current spreading layer 18, and a top ohmic contact layer 19. The first epitaxial region E1 includes a buffer layer 12, a bottom DBR layer 14, a spacer layer 16 and the current spreading layer 18. The active region A includes one or more active layers, an active layer may include a quantum well layer or a multiple quantum well layer. The top ohmic contact layer 19 is disposed above the second epitaxial region E2. The epitaxial structure or the epitaxial layers herein can be epitaxially grown on the substrate by MOCVD.

In the embodiments shown in FIG. 1a or FIG. 1b, the current spreading layer 18 doped with an N-type dopant is inserted in the bottom DBR layer 14. The bottom DBR layer 14 includes alternating pairs of a low refraction layer and a high refraction layer. As shown in FIG. 1a, the current spreading layer 18 is disposed in the bottom DBR layer 14 and is located near the active region A. The current spreading layer 18 can laterally spread current to the layers below the bottom DBR layer 14, thereby reducing the resistance of the bottom DBR layer 14. The lateral direction of the disclosure is parallel (or substantially parallel) to the epi plane direction.

As shown in FIG. 1a, the ohmic contact layer 11 is disposed below the substrate 10. Namely, the substrate 10 is disposed between the ohmic contact layer 11 and the buffer layer 12. Alternatively, as shown in the VCSEL epitaxial structure 101 of FIG. 1b, the ohmic contact layer 11 is disposed between the buffer layer 12 and the bottom DBR layer 14. According to requirements, the ohmic contact layer 11 can be inserted in the buffer layer 12 or the bottom DBR layer 14 (not shown).

Each of the epitaxial layers in the first epitaxial region E1 is an N-type material layer. Each of the epitaxial layers in the second epitaxial region E2 is a P-type material layer. Alternatively, a tunnel junction layer can be disposed in the second epitaxial region E2 such that the second epitaxial region E2 includes a P-type epitaxial layer and N-type epitaxial layer.

### Embodiment 3

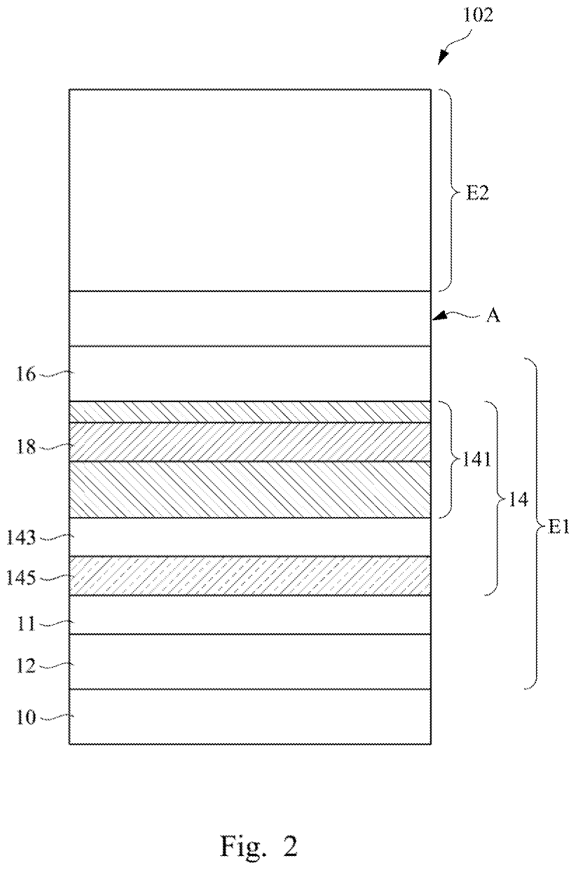

As shown in the VCSEL epitaxial structure 102 of FIG. 2, the bottom DBR layer 14 includes an N-type portion 141, a tunnel junction layer 143, a P-type portion 145, and the current spreading layer 18, wherein the current spreading layer 18 is inserted in the N-type portion 141, and the tunnel junction layer 143 is between the N-type portion 141 and the P-type portion 145. The N-type portion 141 includes a plurality of N-type alternating pairs, the P-type portion 145 includes a plurality of P-type alternating pairs, and the tunnel junction layer 143 is disposed between the N-type portion 141 and the P-type portion 145. Because the P-type alternating pair has a lower interface resistance, the resistance of the bottom DBR layer 14 can be further reduced.

### Embodiment 4

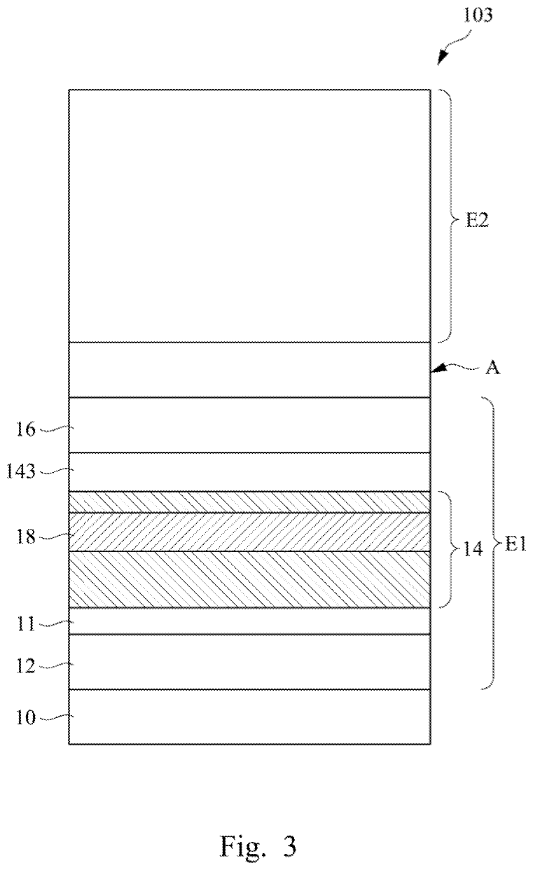

As shown in the VCSEL epitaxial structure 103 of FIG. 3, the tunnel junction layer 143 is disposed between the spacer layer 16 and the bottom DBR layer 14. In the VCSEL epitaxial structure 103 of FIG. 3, each epitaxial layer between the tunnel junction layer 143 and the substrate 10 is N-type material, and the spacer layer 16 between the tunnel junction layer 143 and the active region A is P-type material. The current spreading layer 18 is inserted in the bottom DBR layer 14 and is located near the active region A, wherein the direction of the current is from the active region A towards the substrate 10, but not limited thereto. Therefore, the current can laterally spread in most of the layers in the bottom DBR layer 14, and the current distribution area range of the bottom DBR layer 14 is larger.

In another aspect, it is not easy to laterally spread the current in the substrate 10 when the current passes the substrate 10. By directly or indirectly disposed the current spreading layer 18 on the substrate 10, the current distribution area range in the substrate 1014 is larger. Details thereof are described in the following embodiments. It is noted that the embodiments described below and above can be modified and/or matched.

### Embodiment 5

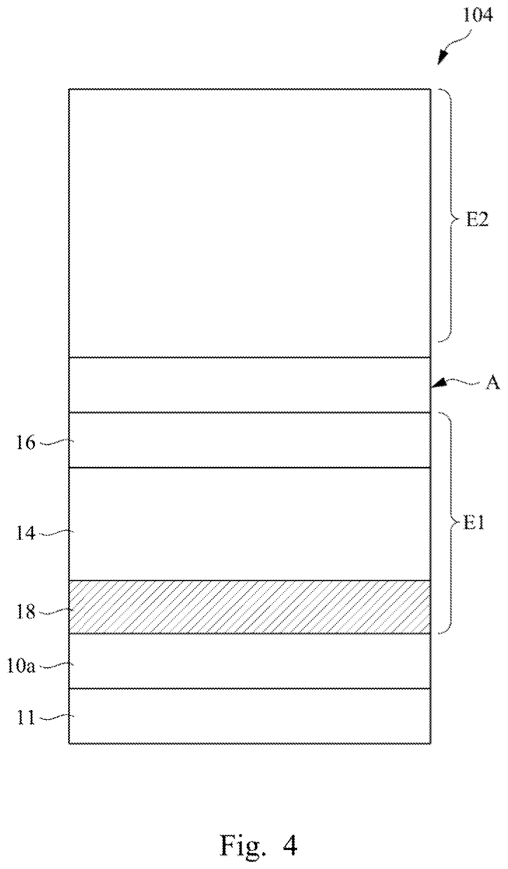

As shown in the VCSEL epitaxial structure 104 of FIG. 4, as the substrate is a conductive substrate 10a, the ohmic contact layer 11 can be disposed below the conductive substrate 10a or disposed over the conductive substrate 10a (not shown). In this embodiment, the current spreading layer 18 is directly disposed on the conductive substrate 10a. A doping concentration of a portion of the current spreading layer 18 is greater than a doping concentration of the conductive substrate 10a.

### Embodiment 6

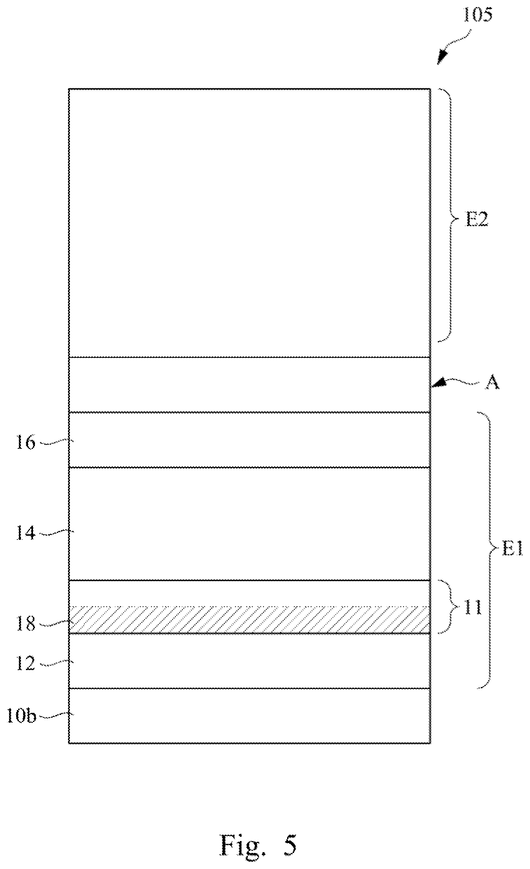

As shown in the VCSEL epitaxial structure 105 of FIG. 5, the substrate is a semi-insulating substrate 10b, and the ohmic contact layer 11 can be disposed over the semi-insulating substrate 10b. Preferably, the current spreading layer 18 is disposed in the ohmic contact layer 11 and is located near the semi-insulating substrate 10b. As shown in FIG. 5, the current spreading layer 18 is disposed between the buffer layer 12 and the ohmic contact layer 11. In other word, the current spreading layer 18 is a lower portion of the ohmic contact layer 11, and an upper portion of the ohmic contact layer 11 is doped with Si, Se, or other suitable element.

In some other embodiments, the current spreading layer 18 is the upper portion of the ohmic contact layer 11, and the lower portion of the ohmic contact layer 11 is doped with Si, Se, or other suitable element. In yet some other embodiments, the current spreading layer 18 is a middle portion of the ohmic contact layer 11, and the upper and/or lower portions of the ohmic contact layer 11 is/are doped with Si, Se, or other suitable element.

### Embodiment 7

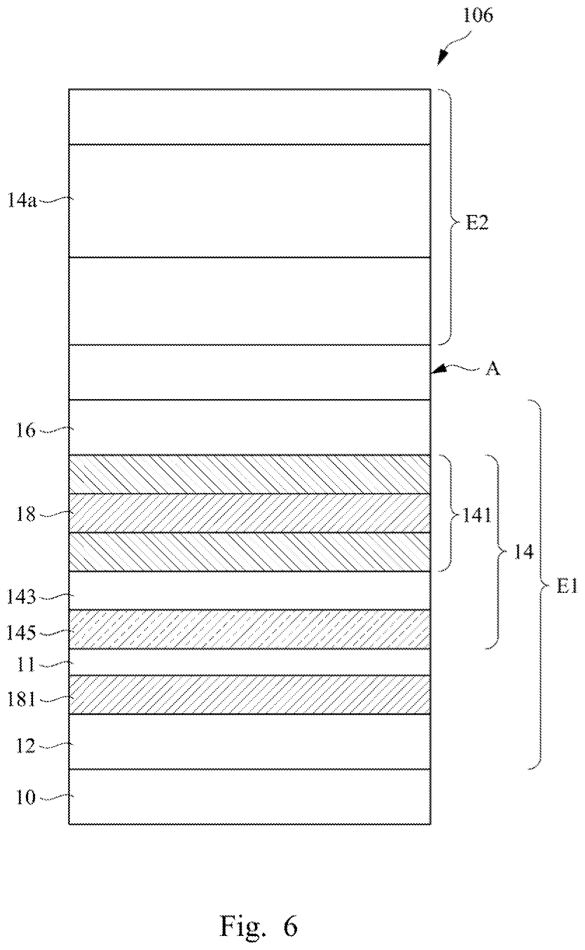

As shown in the VCSEL epitaxial structure 106 of FIG. 6, two current spreading layers 18 and 181 are disposed in the first epitaxial layer E1. The current spreading layer 18 is inserted in the bottom DBR layer 14, and the current spreading layer 181 is disposed between the substrate 10 and the bottom DBR layer 14. In addition, a top DBR layer 14a is disposed in the second epitaxial region E2.

In any one of aforementioned embodiments discussed in FIG. 1a to FIG. 6, preferably, the material of the current spreading layer is GaAs, GaAsSb, InGaAs, InGaAsSb, InGaP, AlGaAs, GaAsP, AlGaInP, or combinations thereof, and the current spreading layer is doped with Se, Si, or other suitable element. In some embodiments, the substrate is made of GaAs, and the N-type current spreading layer includes a material selected from a group consisting of GaAs, GaAsP, InGaP, InGaPN, InGaPSb, InGaPBi, InGaAsP, InAlGaP, InAlGaPN, InAlGaPBi, InAlGaPSb, AlGaAs, AlGaAsP, and AlGaAsSb, in which an Al percentage of the AlGaAs, AlGaAsP, or AlGaAsSb is less than or equal to 30%. If the Al percentage of the N-type current spreading layer is smaller than 30%, the carrier barrier would be lowered, thereby increasing the resistance. In some embodiments, the substrate is made of InP, and the N-type current spreading layer includes a material selected from a group consisting of InGaAs, InGaAsSb, GaAsSb, InP, InGaAsP, InAlAs, InAlGaAs, InAlAsSb, InAlGaAsSb, and AlAsSb.

As a result, the resistance of the VCSEL array having the current spreading layer is less than the conventional VCSEL array. Especially when the density of the VCSEL array is higher, the lateral current spreading effect provided by the current spreading layer is still considerable. Therefore, the power conversion efficiency of the high density VCSEL array is improved, and the optical output power or characteristics of the VCSEL array would not be mitigated.

By appropriately selecting the materials for the current spreading layer and the bottom DBR layers, the conduction band discontinuity (ΔEc) between them can be reduced, resulting in a small carrier barrier and the low resistance wherein the bottom DBR layer is made of GaAs and/or AlGaAs Furthermore, comparing to the P-type current spreading layer, the N-type current spreading layer has lower light-absorbing ability, thus the influence of the optical output power of the VCSEL array can be decreased.

In some embodiments, the doping concentration of the N-type dopant in the current spreading layer is equal to or greater than 4×10¹⁸/cm³. In some embodiments, doping concentration of Se is equal to or greater than 6×10¹⁸/cm³. If the N-type dopant in the current spreading layer is noticeably less than 4×10¹⁸/cm³ or doping concentration of Se is noticeably less than 6×10¹⁸/cm³, the carrier amount provided by the current spreading layer may be insufficient, and thus the current spread ability of the current spreading layer may be poor.

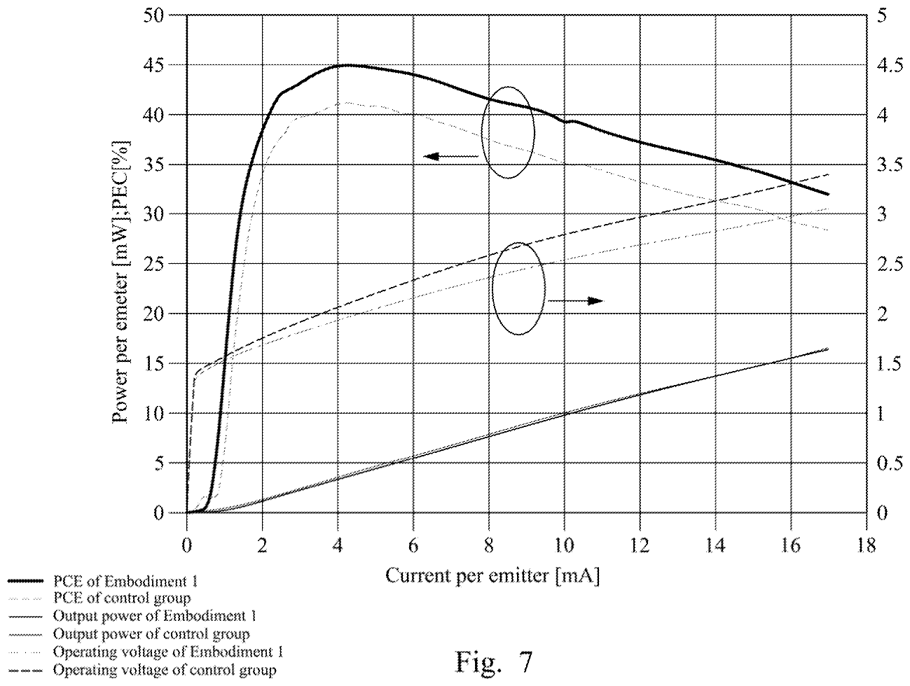

FIG. 7 shows the L-I-V curves for Embodiment 1 and the control group. Both Embodiment 1 and the control group are 940 nm VCSEL array, each having 85 emitters. The distance between any two adjacent emitters (center to center) is about 40 μm, and the bottom DBR layer is composed of GaAs high refractive index layer and AlGaAs low refractive index layer. The current and power conversion efficiency in FIG. 7 are the current and power conversion efficiency of each emitter, which are the average values of total 85 emitters.

The difference between Embodiment 1 and the control group is that the control group didn't have a current spreading layer in the bottom epitaxial layer, while Embodiment 1 had a current spreading layer disposed in the bottom DBR layer (see FIG. 1). The current spreading layer of Embodiment 1 is doped with Si at a doping concentration of 5×10¹⁸/cm³.

As can be seen from FIG. 7, both Embodiment 1 and the control group have the same output power, but Embodiment 1 has a lower operating voltage, indicating that the resistance of the lower DBR layer is lower. Therefore, the power conversion efficiency of Embodiment 1 is significantly better than that of the control group.

In the exemplary embodiments of the current spreading layer being directly or indirectly on the substrate, as illustrated in FIG. 4 or FIG. 5, the current spreading layer can be a quantum well structure. Preferably, the quantum well structure is a stress compensation quantum well structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. A vertical cavity surface-emitting laser epitaxial structure having a current spreading layer, comprising:
a substrate;
a first epitaxial region on the substrate;
an active region on the first epitaxial region; and
a current spreading layer disposed in the first epitaxial region, the current spreading layer comprising an N-type dopant, and the N-type dopant being selected from a group consisting of Si, Se, and the combination thereof, wherein the current spreading layer does not directly contact the active region.

2. The vertical cavity surface-emitting laser epitaxial structure having the current spreading layer of claim 1, wherein the first epitaxial region comprises a bottom distributed Bragg reflector (DBR) layer, the bottom DBR layer does not directly contact the active region, at least of a portion of the bottom DBR layer is an N-type portion, and the current spreading layer is inserted in the N-type portion.

3. The vertical cavity surface-emitting laser epitaxial structure having the current spreading layer of claim 2, wherein the bottom DBR layer comprises a p-type portion and a tunnel junction layer, the tunnel junction layer adjacent the N-type portion and the P-type portion, and the N-type portion is disposed in the bottom DBR layer and is located near the active region.

4. The vertical cavity surface-emitting laser epitaxial structure having the current spreading layer of claim 2, wherein the first epitaxial region comprises a tunnel junction layer disposed between the active region and the current spreading layer or the active region and the bottom DBR layer.

5. The vertical cavity surface-emitting laser epitaxial structure having the current spreading layer of claim 1, wherein the first epitaxial region comprises a spacer layer disposed between the active region and the current spreading layer.

6. The vertical cavity surface-emitting laser epitaxial structure having the current spreading layer of claim 1, wherein the substrate is made of GaAs, and the current spreading layer comprises a material selected from a group consisting of GaAs, GaAsP, InGaP, InGaPN, InGaPSb, InGaPBi, InGaAsP, InAlGaP, InAlGaPN, InAlGaPBi, InAlGaPSb, AlGaAs, AlGaAsP, and AlGaAsSb.

7. The vertical cavity surface-emitting laser epitaxial structure having the current spreading layer of claim 6, wherein an Al percentage of the AlGaAs, AlGaAsP, or AlGaAsSb is less than or equal to 30%.

8. The vertical cavity surface-emitting laser epitaxial structure having the current spreading layer of claim 1, wherein the substrate is made of InP, and the current spreading layer comprises a material selected from a group consisting of InGaAs, InGaAsSb, GaAsSb, InP, InGaAsP, InAlAs, InAlGaAs, InAlAsSb, InAlGaAsSb, and AlAsSb.

9. The vertical cavity surface-emitting laser epitaxial structure having the current spreading layer of claim 1, wherein a doping concentration of the N-type dopant is equal to or greater than 4×10¹⁸/cm³.

10. The vertical cavity surface-emitting laser epitaxial structure having the current spreading layer of claim 1, wherein a doping concentration of Se is equal to or greater than 6×10¹⁸/cm³.

11. A vertical cavity surface-emitting laser epitaxial structure having a current spreading layer, comprising:
a substrate;
a first epitaxial region on the substrate, the first epitaxial region comprising a bottom distributed Bragg reflector (DBR) layer; and
a current spreading layer disposed between the bottom DBR layer and the substrate, the current spreading layer comprising an N-type dopant, and the N-type dopant being selected from a group consisting of Si, Se, and the combination thereof.

12. The vertical cavity surface-emitting laser epitaxial structure having the current spreading layer of claim 11, wherein the substrate is a conductive substrate, and the current spreading layer is disposed between the substrate and the bottom DBR layer, the current spreading layer is directly or indirectly disposed on the substrate.

13. The vertical cavity surface-emitting laser epitaxial structure having the current spreading layer of claim 11, wherein the first epitaxial region comprises an ohmic contact layer, the ohmic contact layer is disposed between the bottom DBR layer and the substrate, and the current spreading layer is disposed between the ohmic contact layer and the substrate.

14. The vertical cavity surface-emitting laser epitaxial structure having the current spreading layer of claim 11, wherein the first epitaxial region comprises an ohmic contact layer, the substrate is a semi-insulating substrate, the ohmic contact layer is disposed between the bottom DBR layer and the substrate, and the current spreading layer is a portion of the ohmic contact layer.

15. The vertical cavity surface-emitting laser epitaxial structure having the current spreading layer of claim 14, wherein the ohmic contact layer comprises a portion and another portion, wherein the another portion is adjacent to the portion, and the current spreading layer is disposed in the portion, the another portion is doped with Si, Se, or combinations thereof.

16. The vertical cavity surface-emitting laser epitaxial structure having the current spreading layer of claim 11, wherein the substrate is made of GaAs, and the current spreading layer comprises a material selected from a group consisting of GaAs, GaAsP, InGaP, InGaPN, InGaPSb, InGaPBi, InGaAsP, InAlGaP, InAlGaPN, InAlGaPBi, InAlGaPSb, AlGaAs, AlGaAsP, and AlGaAsSb, wherein an Al percentage of the AlGaAs, AlGaAsP, or AlGaAsSb is less than or equal to 30%.

17. The vertical cavity surface-emitting laser epitaxial structure having the current spreading layer of claim 11, wherein the substrate is made of InP, and the current spreading layer comprises a material selected from a group consisting of InGaAs, InGaAsSb, GaAsSb, InP, InGaAsP, InAlAs, InAlGaAs, InAlAsSb, InAlGaAsSb, and AlAsSb.

18. The vertical cavity surface-emitting laser epitaxial structure having the current spreading layer of claim 11, wherein a doping concentration of the N-type dopant is equal to or greater than 4×10¹⁸/cm³.

19. The vertical cavity surface-emitting laser epitaxial structure having the current spreading layer of claim 11, wherein a doping concentration of Se is equal to or greater than 6×10¹⁸/cm³.
